(19) United States
(12) Patent Application Publication
(10) Pub. No.: US 2006/0121638 A1
(43) Pub. Date: Jun. 8, 2006

(54) Method of producing nitride-based compound semiconductor light-emitting device

(76) Inventor: Toshio Hata, Mihara-shi (JP)

Correspondence Address: HARNESS, DICKEY & PIERCE, P.L.C., P.O. BOX 8910, RESTON, VA, 20195, US

(21) Appl. No.: 11/294,516

(22) Filed: Dec. 6, 2005

(30) Foreign Application Priority Data
Dec. 6, 2004 (JP) 2004-352344 (P)
Oct. 17, 2005 (JP) 2005-301970 (P)

(51) Int. Cl. H01L 21/28

(52) U.S. Cl. 438/46; 438/459; 438/604

(57) ABSTRACT

A nitride-based compound semiconductor light-emitting device is produced by a method in which a semiconductor layered structure including a plurality of nitride-based compound semiconductor layers is formed on a substrate, the substrate is removed from the semiconductor layered structure by laser irradiation, an exposed surface of the semiconductor layered structure which is a surface exposed by removing the substrate is cleaned, and an electrode is formed on the cleaned exposed surface.

This nonprovisional application is based on Japanese Patent Application Nos. 2004-352344 and 2005-301970 filed with the Japan Patent Office on Dec. 6, 2004 and Oct. 17, 2005, respectively, the entire contents of which are hereby incorporated by reference.

### BACKGROUND OF THE INVENTION

1. Field of the Invention

The present invention relates to a method of producing a nitride-based compound semiconductor light-emitting device (laser and light-emitting diode) that can emit a light in a region from a blue light to an ultraviolet light. In particular, the present invention relates to cleaning of an exposed surface of a semiconductor layered structure, after a substrate is removed from the semiconductor layered structure which has been formed on the substrate.

It is noted that the nitride-based compound semiconductor herein includes InₓAl_{y}Ga_{1-x-y}N (0≦x, 0≦y, x+y≦1).

2. Description of the Background Art

FIG. 7 is a schematic cross-sectional view showing a light-emitting device disclosed in Japanese Patent Laying-Open No. 09-008403. The light-emitting device is produced in the following manner. First, an n-type layer 105 of a gallium nitride-based semiconductor, an active layer 104, a p-type layer 103, and a first ohmic electrode 102 are successively stacked on an electrically-insulating sapphire substrate (not shown). On the other hand, a second ohmic electrode 101 is formed on a p-type electrically-conducting GaAs substrate 100. Then, these first ohmic electrode 102 and second ohmic electrode 101 are bonded to each other by thermocompression bonding. After this, the sapphire substrate is removed by lapping and, as desired, remaining sapphire is also removed by etching. A negative electrode 106 is formed on an exposed surface of n-type layer 105 whic has been exposed as a result of the removal of the sapphire substrate. A positive electrode 107 is formed on the rear surface of p-type GaAs substrate 100.

As described above, according to Japanese Patent Laying-Open No. 09-008403, the sapphire substrate is removed by lapping for the purpose of exposing n-type layer 105 and, as desired, remaining sapphire is also removed by etching.

In some cases, a laser is used to remove a sapphire substrate from a nitride-based compound semiconductor layered structure formed on the sapphire substrate. Specifically, laser radiation from the sapphire substrate side can be used to thermally decompose the compound semiconductor that is in contact with the substrate and thereby remove the substrate. In this case, the whole of the sapphire substrate is removed as it is and thus no sapphire residue remains on the exposed surface of the semiconductor layered structure.

The inventor of the present invention, however, encountered the case where favorable ohmic contact cannot be obtained when an electrode is formed on an exposed surface of a nitride-based compound semiconductor layered structure from which a substrate is removed by laser irradiation.

### SUMMARY OF THE INVENTION

An object of the present invention is thus to make it possible to surely form an electrode having a favorable ohmic property on an exposed surface of a nitride-based compound semiconductor layered structure from which a substrate has been removed by laser irradiation and thereby to provide a nitride-based compound semiconductor light-emitting device having its lower operation voltage and higher reliability.

According to the present invention, a method of producing a nitride-based compound semiconductor light-emitting device includes the steps of: forming a semiconductor layered structure including a plurality of nitride-based compound semiconductor layers on a substrate; removing the substrate from the semiconductor layered structure by laser irradiation; cleaning an exposed surface of the semiconductor layered structure, the exposed surface being a surface exposed by removing the substrate; and forming an electrode on the cleaned exposed surface. By forming the electrode on the cleaned exposed surface, the electrode can have a favorable ohmic property and accordingly it becomes possible to form the nitride-based compound semiconductor light-emitting device having its lower operation voltage and higher reliability.

It is noted that droplets of Ga and the like are generated on the exposed surface of the nitride-based compound semiconductor layered structure, the exposed surface having been exposed by removing the substrate with laser radiation. Therefore, it is preferable that the exposed surface is brought into contact with at least one cleaning agent selected from an acid containing a hydrochloric acid and water (hot water) at a temperature higher than a melting point of Ga. In such cleaning, it is possible to remove undesired residues on the exposed surface by wiping the exposed surface with hot water or soaking the exposed surface in hot water. Further, it is also preferable cleaning to soak the exposed surface in an acid containing a diluted hydrochloric acid which is at room temperature, heated or boiled, or to wipe the exposed surface with the acid. Furthermore, it is more preferable to clean the exposed surface by wiping the exposed surface with hot water and then soaking the exposed surface in hot water and thereafter soaking the exposed surface in a diluted hydrochloric acid.

In the case of no such cleaning, an n-type nitride-based compound semiconductor layer usually serves as a main light radiation surface, and thus residues and Ga-containing droplets generated on the n-type layer by laser irradiation tend to obstruct light emitted from the light-emitting layer, causing deterioration in light extraction efficiency. In contrast, with the exposed surface having been cleaned, the cleaned surface of the n-type nitride based semiconductor layer does not obstruct light emitted from the light-emitting layer, and thus improve the light extraction efficiency.

It is preferable that the exposed surface of the semiconductor layered structure corresponds to an n-type nitride-based compound semiconductor layer. A reason therefor is as follows. In the case where the exposed surface corresponds to an n-type nitride-based compound semiconductor layer, the n-type layer is superior in electrical conductivity to a p-type layer and thus can be formed to have a large thickness. Therefore, when the n-type layer is irradiated with laser light and brought into contact with hot water, a diluted hydrochloric acid or the like, damage to the thick n-type layer is advantageously small. Further, damage to the light-emitting layer located under the thick n-type layer is also small.

The wavelength of laser irradiation to be employed may be in a range of 200 nm to 1100 nm, and laser irradiation with a wavelength of 248 nm, 266 nm or 355 nm for example can preferably be used, since laser irradiation with such a wavelength can be used to form a favorable exposed surface where there are less residues before cleaning.

On the cleaned exposed surface of the nitride-based compound semiconductor layer, a favorable ohmic electrode can be formed on an arbitrary region that is a part or the whole of the exposed surface.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view showing a nitride-based compound semiconductor light-emitting device according to a first embodiment of the present invention.

FIGS. 2 and 3 are schematic cross-sectional views for illustrating steps of producing the nitride-based compound semiconductor light-emitting device in the first embodiment.

FIG. 4 is a schematic cross-sectional view showing a nitride-based compound semiconductor light-emitting device according to a second embodiment of the present invention.

FIGS. 5 and 6 are schematic cross-sectional views for illustrating steps of producing the nitride-based compound semiconductor light-emitting device in the second embodiment.

FIG. 7 is a schematic cross-sectional view showing a conventional nitride-based compound semiconductor light-emitting device.

### DESCRIPTION OF THE PREFERRED EMBODIMENTS

As described above, when laser irradiation is used to remove a sapphire substrate from a nitride-based compound semiconductor layered structure on the substrate, the whole of the sapphire substrate is removed as it is and no sapphire residue remains on the exposed surface of the semiconductor layered structure. The inventor of the present invention, however, encountered the case where favorable ohmic contact cannot be obtained when an electrode is formed on an exposed surface of a nitride-based semiconductor layered structure from which a substrate is removed by laser irradiation. According to the inventor's investigation on the reason of this, it is found that although no substrate residue is left on the exposed surface of the nitride-based semiconductor layered structure after the laser radiation, droplets of Ga and the like as well as droplets containing Ga are left on the exposed surface. It is considered that these droplets are likely to disturb the electronic state on the surface and to hinder formation of a favorable ohmic contact.

In the case of using laser irradiation to remove a substrate from a nitride-based compound semiconductor layered structure, therefore, the inventor conducted investigation on a method of removing residues on a semiconductor surface exposed as a result of the removal of the substrate and thereby cleaning the semiconductor surface. Consequently, it is found that a nitride-based compound semiconductor light-emitting device having its lower operation voltage and high reliability can be produced by removing residues on an exposed surface of a nitride-based compound semiconductor layered structure in a simple and low-cost manner thereby cleaning the exposed surface and then forming an electrode having a favorable ohmic property on the cleaned surface.

### First Embodiment

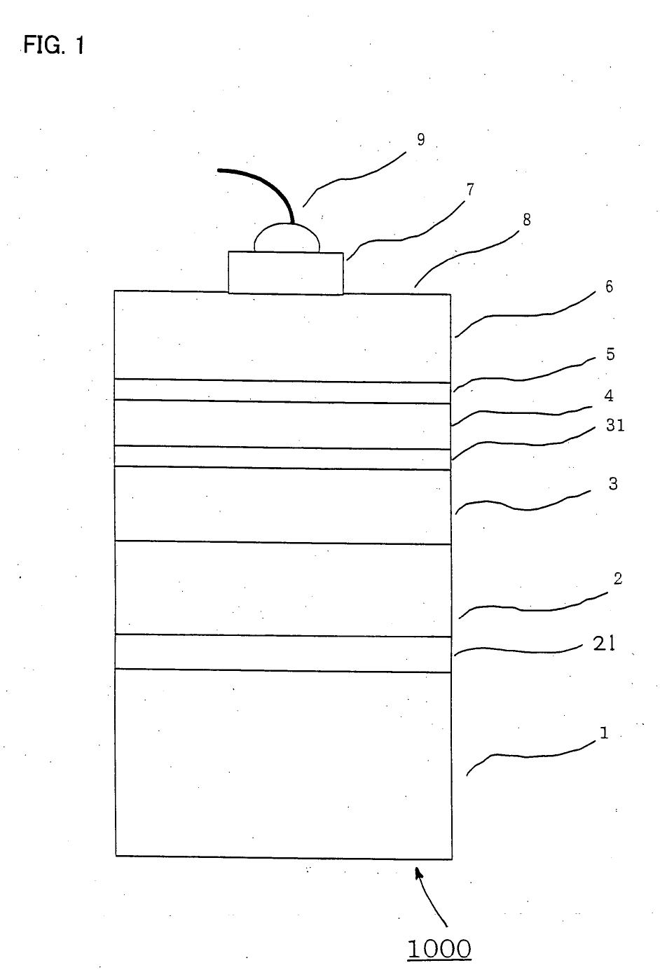

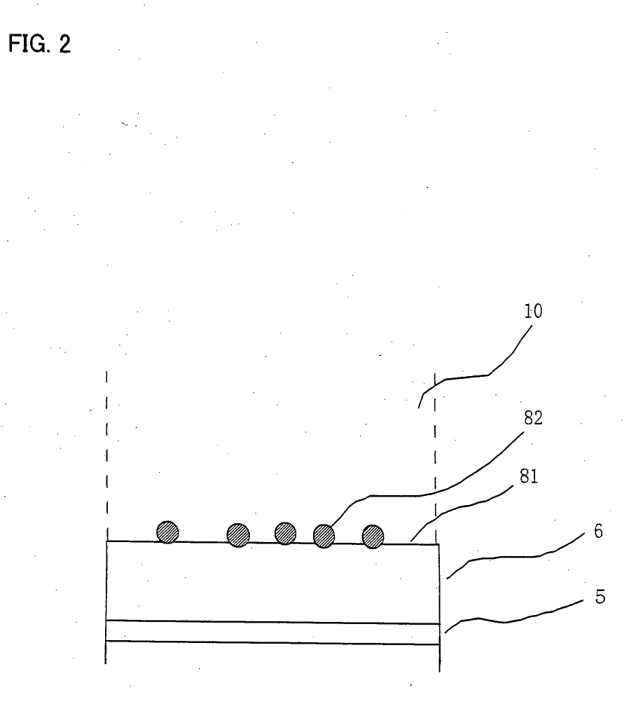

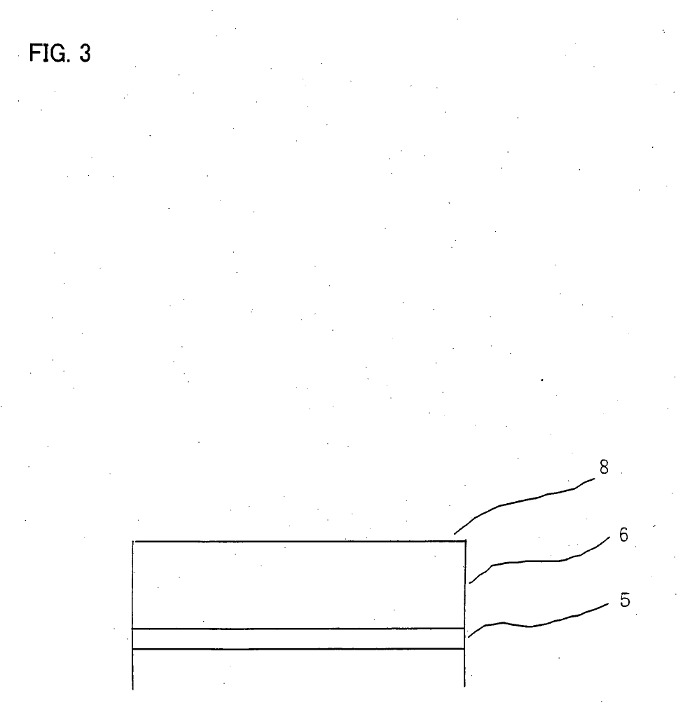

FIG. 1 is a schematic cross-sectional view showing a nitride-based compound semiconductor light-emitting device according to a first embodiment of the present invention, and FIGS. 2 and 3 are schematic cross-sectional views illustrating steps of producing the light-emitting device in FIG. 1. Specifically, light-emitting device 1000 of FIG. 1 can be produced through the following steps (1a) to (8a), for example.

(1a) A GaN buffer layer of 30 nm thickness (not shown), an n-type nitride-based compound semiconductor layer 6 of 9 μm thickness, an MQW (multiple quantum well) light-emitting layer 5 of 50 nm thickness, and a p-type nitride-based compound semiconductor layer 4 of 200 nm thickness are successively grown on a sapphire substrate 10 (see FIG. 2). For example, an MOCVD (metal-organic chemical vapor deposition) method can be used to deposit these semiconductor layers.

(2a) An ohmic Pd electrode 31 of 4.5 nm thickness, a reflective Ag metal layer 3 of 150 nm thickness and a bonding AuSn metal layer 2 of 3 μm thickness are successively deposited by evaporation on p-type nitride-based compound semiconductor layer 4. EB (electron beam) evaporation or resistance-heating evaporation can be used for the vapor phase deposition of the electrode and layers. The AuSn alloy may contain 20 wt % Sn, for example.

(3a) A bonding Au metal layer 21 of 1 μm thickness is formed on a support Si substrate 1 by EB evaporaton.

(4a) Bonding Au metal layer 21 and bonding AuSn metal layer 2 are arranged to face and contact each other, and then these layers are bonded to each other at a temperature of 290° C. and under a pressure of 3 N/cm² by eutectic bonding.

(5a) YAG-THG (yttrium-aluminum-garnet, third-harmonic-generation) laser irradiation (355 nm in wavelength) through sapphire substrate 10 that has been mirror-polished is used to thermally decompose the GaN buffer layer which is in contact with sapphire substrate 10 and a part of n-type GaN layer 6 and thereby remove sapphire substrate 10. At this time, Ga droplets 82 are generated on an exposed surface 81 of n-type GaN layer 6 (see FIG. 2). This exposed surface 81 and droplets of Ga or droplets containing elements of Ga, Si, etc. 82 are soaked in hot water of 100° C. and then exposed surface 81 is wiped with a cloth material (Bemcot for example), so that a cleaned exposed surface 8 is obtained as shown in FIG. 3. In this case, tap water, pure water, ultrapure water, purified water or the like can be used for the hot water.

(6a) Using a resist mask, RIE (reactive ion etching) is carried out from n-type GaN layer 6 side to completely remove part of the succeeding layers up to and including p-type nitride-based compound semiconductor layer 4, thereby forming grooves for chip division and exposing such a component as ohmic electrode 31 or reflective metal layer 3. Here, the grooves formed by the RIE may have a width of approximately 501m, for example.

(7a) An n-type bonding pad electrode (Au/Ti/Al/Ti) 7 is formed on the cleaned exposed surface of n-type GaN layer 6.

(8a) The inside of the grooves formed by the RIE is irradiated with YAG-THG laser light (355 nm in wavelength) to form grooves for chip division having an intermediate depth within support Si substrate 1. Then, a scriber of an infrared-transmission type is used to make marking lines from the rear side of support Si substrate 1 so that the marking lines are opposite to the corresponding grooves for chip division. The step of producing chips is completed by division along the marking lines. Thereafter, an An wire 9 is ball-bonded on n-type bonding pad 7. Accordingly, the process of producing the nitride-based compound semiconductor light-emitting device is completed.

In the first embodiment, Ga droplets 82 which are generated on exposed surface 81 of the n-type nitride-based compound semiconductor layer in the step of removing sapphire substrate 10 by laser irradiation can be removed to form clean surface 8 of the n-type nitride-based compound semiconductor layer, and then n-type electrode 7 can be provided on this exposed surface 8 to form an electrode of favorable ohmic contact. In this case, the hot water can be used to remove Ga droplets in an easy and simple manner. Incidentally, a branch-shaped pad electrode may be formed as the pad electrode.

### Second Embodiment

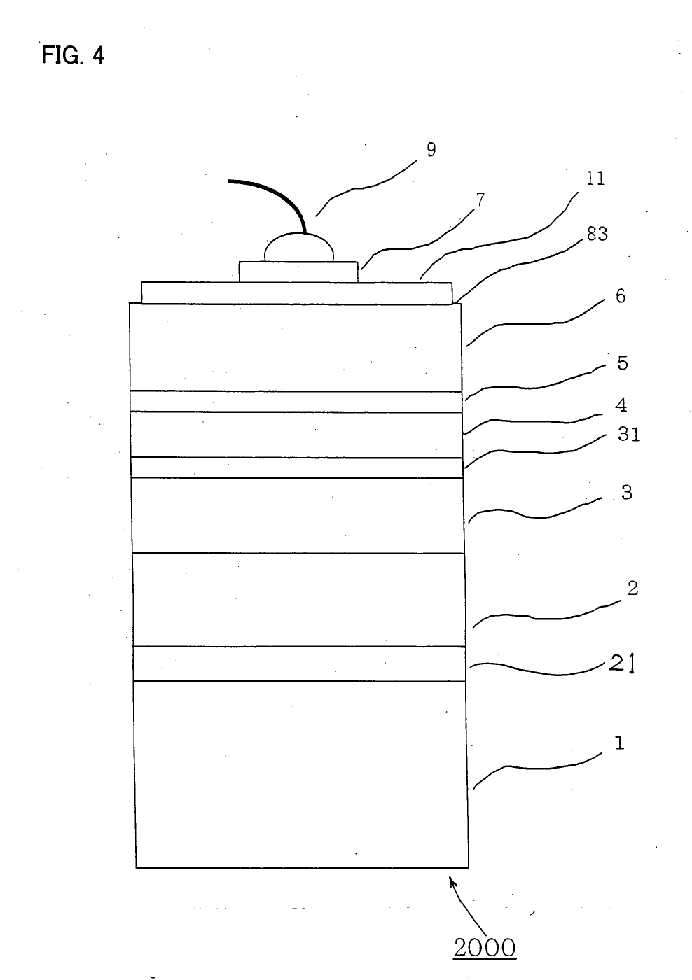

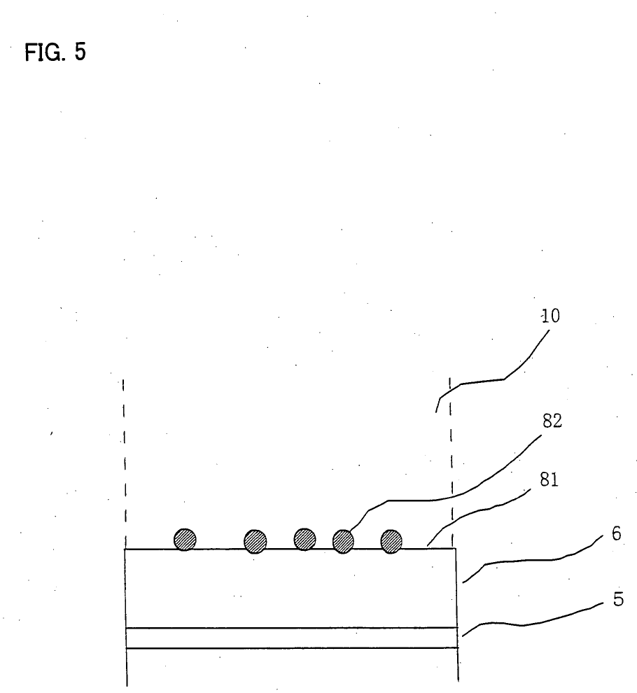

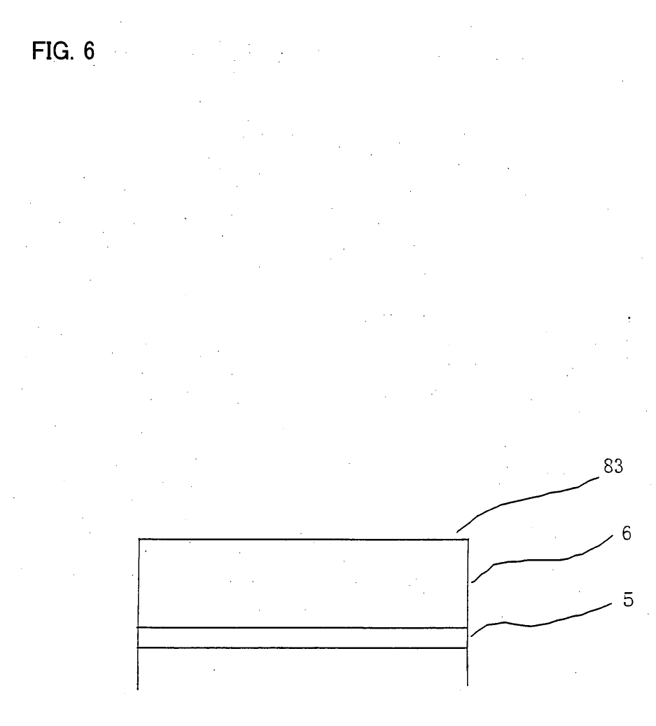

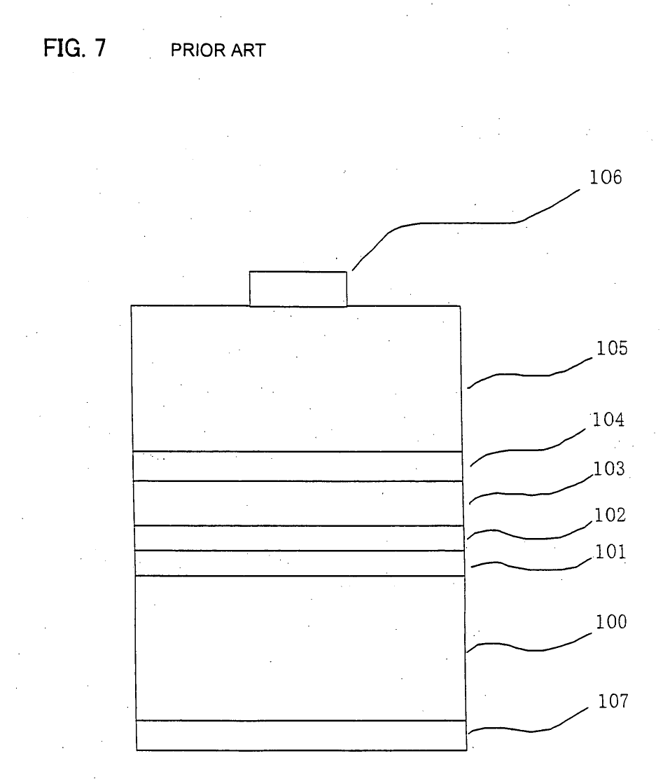

FIG. 4 is a schematic cross-sectional view showing a nitride-based compound semiconductor light-emitting device according to a second embodiment of the present invention, and FIGS. 5 and 6 are schematic cross-sectional views illustrating steps of producing the light-emitting device of FIG. 4. Specifically, light-emitting device 2000 of FIG. 4 can be produced through the following steps (1b) to (8b), for example.

(1b) A GaN buffer layer of 50 nm thickness (not shown), an n-type nitride-based compound semiconductor layer 6 of 7 μm thickness, an MQW light-emitting layer 5 of 50 nm thickness, and a p-type nitride-based compound semiconductor layer 4 of 200 nm thickness are successively grown on a sapphire substrate 10 (see FIG. 5). For example, an MOCVD method can be used to deposit these semiconductor layers.

(2b) An ohmic Pd electrode 31 of 4.5 nm thickness, a reflective Ag—Nd metal layer 3 of 200 nm thickness and a bonding AuSn metal layer 2 of 3 μm thickness are successively deposited by evaporation on p-type nitride-based compound semiconductor layer 4. EB evaporation or resistance-heating evaporation can be used for the vapor phase deposition of the electrode and layers. The AuSn alloy may contain 20 wt % Sn, for example.

(3b) A bonding Au metal layer 21 of 1 μm thickness is formed on a support Si substrate 1 by EB evaporation.

(4b) Bonding Au metal layer 21 and bonding AuSn metal layer 2 are arranged to face and contact each other, and then these layers are bonded to each other at a temperature of 320° C. and under a pressure of 3 N/cm² by eutectic bonding.

(5b) YAG-FHG (yttrium-aluminum-garnet, fourth-harmonic-generation) laser irradiation (266 nm in wavelength) through the sapphire substrate that has been mirror-polished is used to thermally decompose the GaN buffer layer which is in contact with sapphire substrate 10 and part of n-type GaN layer 6 and thereby remove sapphire substrate 10. At this time, droplets of Ga or droplets containing elements of Ga, Si, etc. 82 are generated on an exposed surface 81 of n-type GaN layer 6 (see FIG. 5). This exposed surface 81 and droplets of Ga or droplets containing elements of Ga, Si, etc. 82 are soaked in hot water at a temperature of 100° C. Then, exposed surface 81 is wiped with a cloth material (Bemcot for example), and further soaked in a hydrochloric acid at room temperature for approximately two minutes, so that a cleaned exposed surface 83 is obtained as shown in FIG. 6. Here, a diluted hydrochloric acid or an acid containing at least a hydrochloric acid may also be used instead of the hydrochloric acid.

(6b) Using a resist mask, RIE is carried out from n-type GaN layer 6 side to remove part of the succeeding layers up to and including p-type nitride-based compound semiconductor layer 4, thereby forming grooves for chip division. Here, the grooves formed by the RIE may have a depth of approximately 3 μm and; a width of approximately 50 μm.

(7b) A transparent electrically-conductive film 11 of ITO (indium tin oxide) is formed on the substantially entire surface of the cleaned exposed surface of n-type GaN layer 6. A bonding pad electrode (Au/Ti/Al/Ti) 7 is formed on this transparent electrically-conductive film 11. An extremely thin translucent metal film may also be formed instead of ITO electrically-conductive film 11.

(8b) YAG-THG laser irradiation (355 nm in wavelength) opposite to the grooves formed by the RIE is carried out so as to form laser scribe lines on the rear side of support Si substrate 1. The step of producing chips is completed by division along the laser scribe lines. Thereafter, an Au wire 9 is ball-bonded on bonding pad 7. Accordingly, the process of producing the nitride-based compound semiconductor light-emitting device is completed.

In the second embodiment, Ga droplets 82 which are generated on exposed surface 81 of the n-type nitride-based compound semiconductor layer in the step of removing sapphire substrate 10 by laser irradiation can be removed to form clean surface 83 of the n-type nitride-based compound semiconductor layer, and then the n-type electrode can be provided on this exposed surface to form an electrode of favorable ohmic contact. In this case, the hot water and a diluted hydrochloric acid can be used to remove Ga droplets in the easy and simple manner. As compared with the first embodiment, the second embodiment can make exposed surface 81 of the n-type nitride-based compound semiconductor layer 6 cleaner and thus it is possible to form an electrode of more favorable ohmic contact thereon.

In the second embodiment as well, ohmic electrode 31 or reflective metal layer 3 may be exposed in the step of forming grooves for chip division by RIE. Further, according to the present invention, a layer of Ni, Ti, W, etc., or an alloy layer of Ni—Ti or the like may be formed as a barrier layer between reflective metal layer 3 and bonding metal layer 2. Further, the temperature of the hot water used for the cleaning is preferably more than a melting point of Ga, and the temperature of the diluted hydrochloric acid is preferably at least room temperature and at most 110° C. In the case where transparent electrically-conductive electrode 7 is formed on the substantially entire surface of n-type GaN layer 6, a branch-shaped pad electrode may be formed thereon. Furthermore, although the above-described embodiments use laser irradiation with a wavelength of 266 nm and laser radiation with a wavelength of 355 nm by way of example, the present invention may also use laser radiation with its wavelength in a range of 200 to 1100 nm. For example, KrF excimer laser irradiation with a wavelength of 248 nm can also be used preferably.

As heretofore discussed, according to the present invention, an electrode having a favorable ohmic property can surely be formed on an exposed surface of a nitride-based compound semiconductor layered structure from which a substrate has been removed by laser irradiation. Accordingly, it is possible to provide a nitride-based compound semiconductor light-emitting device having its lower operation voltage and higher reliability.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A method of producing a nitride-based compound semiconductor light-emitting device, comprising the steps of:
forming a semiconductor layered structure including a plurality of nitride-based compound semiconductor layers on a substrate;
removing said substrate from said semiconductor layered structure by laser irradiation;
cleaning an exposed surface of said semiconductor layered structure, the exposed surface being a surface exposed by removing said substrate; and
forming an electrode on said cleaned exposed surface.

2. The method of producing a nitride-based compound semiconductor light-emitting device according to claim 1, wherein
Ga droplets are generated on said exposed surface of said semiconductor layered structure, the surface having been exposed by removing said substrate with said laser irradiation, and then in said step of cleaning, said exposed surface is brought into contact with at least one cleaning agent selected from water having a controlled temperature of more than a melting point of Ga and an acid containing a hydrochloric acid.

3. The method of producing a nitride-based compound semiconductor light-emitting device according to claim 2, wherein
said water having a controlled temperature is one of tapped water, pure water, ultrapure water and purified water.

4. The method of producing a nitride-based compound semiconductor light-emitting device according to claim 2, wherein
said acid containing a hydrochloric acid is a hydrochloric acid or an acid containing at least a diluted hydrochloric acid.

5. The method of producing a nitride-based compound semiconductor light-emitting device according to claim 2, wherein
said cleaning agent is used at a temperature of at least room temperature.

6. The method of producing a nitride-based compound semiconductor light-emitting device according to claim 1, wherein
said exposed surface is an n-type nitride-based compound semiconductor layer.

7. The method of producing a nitride-based compound semiconductor light-emitting device according to claim 1, wherein
said laser irradiation has a wavelength in a range of 200 nm to 1100 nm.

8. The method of producing a nitride-based compound semiconductor light-emitting device according to claim 1, wherein
an electrode is formed on part of said cleaned exposed surface.

9. The method of producing a nitride-based compound semiconductor light-emitting device according to claim 1, wherein
a transparent or translucent electrode is formed on the whole of said cleaned exposed surface.
